(19) United States
(12) Patent Application Publication
(10) Pub. No.: US 2025/0374375 A1
(43) Pub. Date: Dec. 4, 2025

(54) ULTRA-FAST TEMPERATURE SWITCHING PEDESTAL

(71) Applicant: Applied Materials, Inc., Santa Clara, CA (US)

(72) Inventors: ANANTHA K. SUBRAMANI, San Jose, CA (US); SEYYED FAZELI, Santa Clara, CA (US); FARZAD HOUSHMAND, Mountain View, CA (US); SATISH RADHAKRISHNAN, San Jose, CA (US); CHI MA, Santa Clara, CA (US); RAMCHARAN SUNDAR, Chennai (IN); MICHELLE SANPEDRO, Santa Clara, CA (US)

(21) Appl. No.: 18/731,192

(22) Filed: May 31, 2024

(51) Int. Cl. H05B 1/02; C23C 16/458; C23C 16/46; H05B 3/04

(52) U.S. Cl. CPC H05B 1/0233; C23C 16/4586; C23C 16/466; H05B 3/04

(57) ABSTRACT

Embodiments described herein relate to an apparatus that includes a first plate with an embedded channel that has a seamless surface, and where the first plate includes a metallic material. In an embodiment, the apparatus further includes a second plate over the first plate, where the second plate is spaced apart from the first plate by a gap. In an embodiment, a heating element is embedded within the second plate.

### BACKGROUND

### 1) Field

Embodiments of the present disclosure pertain to the field of semiconductor manufacturing and pedestal temperature control.

### 2) Description of Related Art

In semiconductor manufacturing, precise control of processing conditions is necessary in order to provide high yielding devices. One process condition that is controlled in many process recipes is a temperature of the substrate (e.g., a semiconductor wafer). The temperature of the substrate is often controlled by the chuck or pedestal on which the substrate is supported. For example, the pedestal may include heating elements in order to provide a desired temperature for the substrate.

In some instances, multiple operations are used in a process recipe in order to provide a desired process result on a substrate. For example, a deposition process may use a first substrate temperature at a beginning of the deposition process and a second substrate temperature at an end of the process. For example, a high first temperature may be used to nucleate a material layer, and a lower second temperature may be used to continue the deposition of the material layer until the desired thickness is reached.

### SUMMARY

Embodiments described herein relate to an apparatus that includes a first plate with an embedded channel that has a seamless surface, and where the first plate includes a metallic material. In an embodiment, the apparatus further includes a second plate over the first plate, where the second plate is spaced apart from the first plate by a gap. In an embodiment, a heating element is embedded within the second plate.

Embodiments described herein relate to a pedestal that includes a first plate, where the first plate is configured to be held at a first temperature by a cooled liquid that passes through a channel embedded within the first plate, and where the first plate is a monolithic metallic structure. In an embodiment, the pedestal further includes a second plate above the first plate, where the second plate is configured to be held at a second temperature that is higher than the first temperature by a heating element embedded in the second plate. In an embodiment, the pedestal includes a gap between the first plate and the second plate, where initiating a flow of a gas through the gap reduces a temperature of the second plate to a third temperature that is between the first temperature and the second temperature.

Embodiments described herein relate to a method that comprises maintaining a temperature of a surface of a pedestal at a first temperature, where the pedestal comprises a first plate that is spaced apart from a second plate by a gap, and where the second plate is configured to be held at the first temperature and the first plate is configured to be held at a second temperature that is less than the first temperature. In an embodiment, the method further comprises flowing a gas into the gap, and reducing the temperature of the surface of the pedestal to a third temperature that is between the first temperature and the second temperature.

Embodiments described herein relate to a method that includes nucleating a material layer on a substrate that is supported by a pedestal that has a surface that is held at a first temperature, and reducing a temperature of the surface of the pedestal to a second temperature by increasing a flow of gas between a first plate of the pedestal and a second plate of the pedestal. In an embodiment, the first plate of the pedestal is held at a third temperature that is lower than the second temperature, and the surface of the pedestal is part of the second plate of the pedestal. The method may also include increasing a thickness of the material layer through continued deposition of the material while the surface of the pedestal is held at the second temperature.

### BRIEF DESCRIPTION OF THE DRAWINGS

FIG. 1A is cross-sectional illustration of a portion of a pedestal with a first plate with fluidic channels that is spaced apart from a second plate with a heating element by a gap, in accordance with an embodiment.

FIG. 1B is an equivalent diagram of the thermal resistance through the pedestal, in accordance with an embodiment.

FIG. 2A is a plan view illustration of the first plate of the pedestal with an embedded fluidic path, in accordance with an embodiment.

FIG. 2B is a plan view illustration of the first plate showing a gas distribution path used to rapidly decrease a temperature of an overlying first plate of the pedestal, in accordance with an embodiment.

FIG. 3A is a cross-sectional illustration of a pedestal with a first plate with a plurality of fluidic paths that is spaced apart from the second plate by a gap, in accordance with an embodiment.

FIG. 3B is a cross-sectional illustration of a pedestal with a first plate with a fluidic path and a cavity that is spaced apart from the second plate by a gap, in accordance with an embodiment.

FIG. 4 is a cross-sectional illustration of a portion of the pedestal that illustrates an edge region of the pedestal, in accordance with an embodiment.

FIG. 5 is a cross-sectional illustration of a portion of the pedestal that illustrates a lift pin opening through the first plate, in accordance with an embodiment.

FIG. 6 is a process flow diagram of a process for rapidly decreasing a temperature of a pedestal, in accordance with an embodiment.

FIG. 7 is a process flow diagram of a process for depositing a material on a substrate with a first duration at a first temperature and a second duration at a second temperature, in accordance with an embodiment.

FIG. 8 illustrates a block diagram of an exemplary computer system of a processing tool, in accordance with an embodiment of the present disclosure.

### DETAILED DESCRIPTION

Pedestals for vacuum chambers that are manufactured with three-dimensional (3D) printing processes are described, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, some semiconductor manufacturing processes use a multi-temperature process flow. For example, a first substrate temperature may be used for a first portion of the process (e.g., a nucleation operation), and a second temperature may be used for a second portion of the process (e.g., continued deposition of a material). In the case of tungsten deposition, the tungsten layer may be nucleated on the substrate at a temperature around 450° C., while the continued deposition is optimally executed at around 350° C. The ability to quickly switch between temperatures is desirable in order to decrease the duration of the process and/or to provide better processing results.

However, existing pedestal and chucking solutions rely on a heated pedestal or chuck. There is not currently a configuration that allows for rapid cooling of the heated pedestal or chuck. This is due, at least in part, to restrictions related to flowing fluids within the vacuum chamber. Vacuum chamber design rules state that no fluid can flow through channels (e.g., tubes, paths, conduits, or the like) that are brazed or otherwise include a sealed interface. This is because any defect in the seal will result in the cooling fluid entering the vacuum chamber. The presence of cooling fluid within the chamber would result in significant damage to the chamber and/or the substrates being processed in the chamber. Since it is exceedingly difficult to the manufacture blind channels in a solid block of material, liquid cooling of the pedestal is not currently feasible in vacuum chamber environments.

Accordingly, embodiments disclosed herein include a pedestal structure that includes an actively heated plate with an actively cooled plate below the actively heated plate. A gap is provided between the actively heated plate and the actively cooled plate. When the actively heated plate (that supports the substrate) needs to be cooled, a gas is flown in the gap in order to increase heat transfer from the actively heated plate to the actively cooled plate in order to rapidly cool the actively heated plate. That is, the heat transfer between the heated plate and the cooled plate is controlled through the modulation of the convective heat transfer between the heated plate and the cooled plate.

In some embodiments, the temperature change of the heated plate may include a drop in a temperature of the heated plate by 50° C. or more, or 100° C. or more. Further, the temperature change may be completed in about one minute or less, about forty five seconds or less, or about thirty seconds or less. For example, flowing gas in the gap at a higher flow rate may increase the convective cooling between the heated plate and the cooled plate.

In an embodiment, the actively cooled plate is cooled with a cooling fluid. In order to meet design rules, the cooling channels within the actively cooled plate are formed with a three-dimensional (3D) printing process. Accordingly, the cooling channels do not have any lids, seals, or the like that need to be secured (e.g., with a brazing process or the like). The actively cooled plate may be a high thermal conductivity material, such as aluminum or the like. In some embodiments, the cooled plate may be referred to as a heatsink. The gap between the cooled plate and the heated plate thermally isolates the two plates from each other in some conditions (e.g., when there is no gas flowing through the gap). When rapid cooling is desired, the cooled plate is thermally coupled to the heated plate by flowing a gas through the gap.

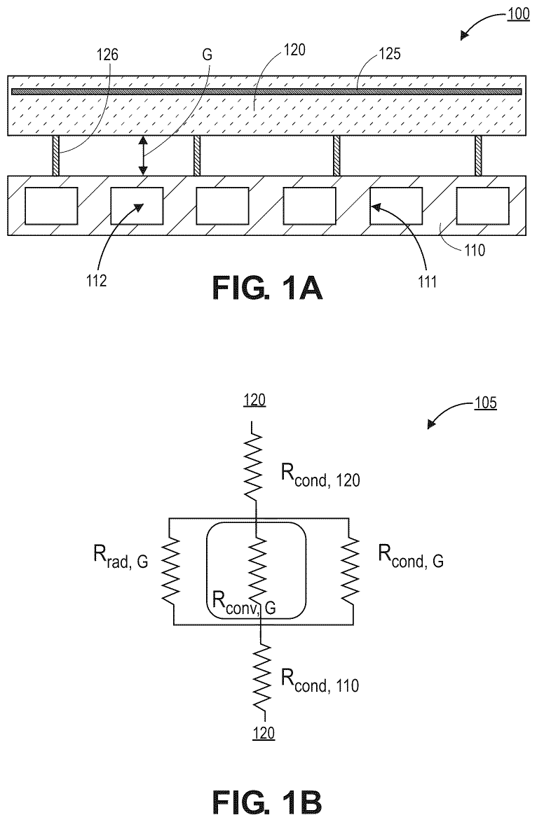

Referring now to FIG. 1A, a cross-sectional illustration of a portion of a pedestal 100 is shown, in accordance with an embodiment. The pedestal 100 may be a structure used to support a substrate (not shown) within a chamber. The pedestal 100 may include chucking functionality in order to secure the substrate. In some embodiments, the pedestal 100 may include a vacuum chuck or an electrostatic chuck (ESC). The chamber may be a vacuum chamber suitable for implementing one or more processes, such as deposition, etching, plasma treatment, annealing, or the like. For example, deposition processes may include chemical vapor deposition (CVD), plasma enhanced CVD (PECVD), atomic layer deposition (ALD), plasma enhanced ALD (PEALD), physical vapor deposition (PVD), or the like. Etching processes may include plasma etching processes, or other subtractive processes.

In the illustrated embodiment, the portion of the pedestal 100 that is shown includes a first plate 110 and a second plate 120. The first plate 110 may be separated from the second plate 120 by a gap G. In an embodiment, the gap G may be up to up to approximately 750 μm, up to approximately 500 μm, up to approximately 250 μm, or up to approximately 100 μm. Though, larger gaps G may also be used in some embodiments. In some instances the second plate 120 may be supported over the first plate 110 by one or more support structures 126. Though, other embodiments may include a pedestal 100 that omits support structures 126 between the first plate 110 and the second plate 120. In an embodiment, the support structures 126 comprise a material with a low thermal conductivity in order to prevent thermal communication between the first plate 110 and the second plate 120. For example, the support structures 126 may be an alloy comprising nickel, cobalt, and iron. Additionally, a cross-sectional area of the support structures 126 may be minimized in order to reduce the area of the thermal path between the first plate 110 and the second plate 120.

In an embodiment, the first plate 110 may be actively cooled. For example, a cooling fluid (not shown) may be flown through channels 112 embedded within the first plate 110. The cooling fluid may comprise one or more of water, ethylene glycol, oil, and/or the like. In an embodiment, the cooling fluid is cooled in a refrigeration unit or the like outside of the chamber. The cooling fluid is used to maintain a temperature of the first plate 110 at a temperature below expected process recipe temperatures.

In an embodiment, the channels 112 of the first plate 110 may comprise a seamless surface 111. That is, a cross-section of the channels 112 may not include any seams. As such, there is no need for brazing or any other attachment mechanism to mechanically couple distinct components together in order to form the embedded channels 112. The ability to have a seamless surface 111 allows for the pedestal 100 to conform to vacuum chamber design rules. Accordingly, fluids can be flown through the pedestal 100.

In an embodiment, the seamless surface 111 is enabled through the manufacturing process used to form the first plate 110. Particularly, the first plate 110 may be manufactured as a monolithic structure (i.e., one continuous piece) through three-dimensional (3D) printing processes. In an embodiment, channels 112 may have substantially rectangular cross-sections, as shown in FIG. 1A. Though, the 3D printing process may result in surfaces 111 (e.g., sidewalls, top, or bottom) that are curved or otherwise non-planar. In some embodiments, a bottom of the channel 112 may be wider than a top of the channel 112. For example, the channel 112 may have a triangular-like shaped cross-section in some embodiments. It is to be appreciated that such non-planar and/or tapered surfaces 111 may be an indication that 3D printing processes were used to form the monolithic first plate 110 with fully embedded channels 112. In an embodiment, the first plate 110 may be a material with a high thermal conductivity in order to improve heat transfer. For example, the first plate 110 may comprise a metallic material, such as one comprising aluminum or the like.

In an embodiment, the second plate 120 may comprise a ceramic material suitable for supporting substrates within a processing chamber. The second plate 120 may comprise a heating element 125. For example, the heating element 125 may be a resistive heater or the like. The heating element 125 can be used to set a temperature of the second plate 120 in accordance with a given process recipe for processing the substrate in the chamber.

As can be appreciated, the first plate 110 and the second plate 120 are thermally isolated from each other by the gap G. However, when a temperature of the second plate 120 needs to be reduced, a gas may be flown through the gap G. Flowing the gas through the gap G may increase a convective heat transfer from the second plate 120 into the first plate 110. Accordingly, control of the gas flow rate can be used to control a temperature drop in the second plate 120.

Referring now to FIG. 1B, an equivalent diagram 105 of the thermal resistance between the first plate 110 and the second plate 120 is shown, in accordance with an embodiment. As shown, the first plate 110 has a first conductive thermal resistance R_{cond}, 110 and the second plate 120 has a second conductive thermal resistance R_{cond}, 120. The gap G between the first plate 110 and the second plate 120 includes three different modes of heat transfer: radiative R_{rad, G}, conductive R_{cond, G}, and convective R_{conv, G}. The radiative component, and the conductive component of the gap G may both remain substantially constant. However, the convective component R_{conv, G} can be controlled in order to rapidly increase heat transfer from the second plate 120 to the first plate 110. As noted above, increasing the flow rate of gas through the gap G can be used in order to rapidly decrease a temperature of the second plate 120. For example, a drop in a temperature of the second plate 120 may be approximately 50° C. or more, or approximately 100° C. or more. Further, the temperature change may be completed in about one minute or less, about forty five seconds or less, or about thirty seconds or less. In an embodiment, the gas that is flown through the gap may include one or more of hydrogen, nitrogen, helium, or any other inert gas.

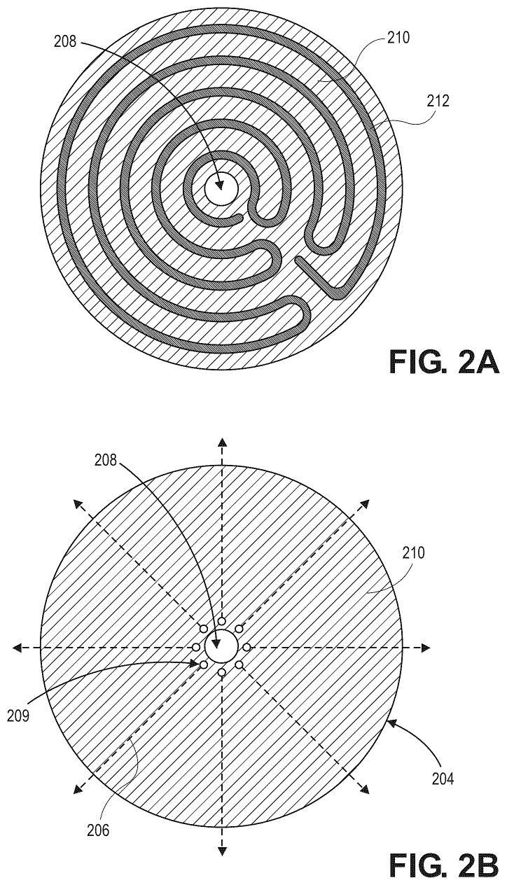

Referring now to FIG. 2A, a plan view illustration of a first plate 210 is shown, in accordance with an embodiment. In an embodiment, the first plate 210 may be similar to the first plate 110 described in greater detail herein. As shown, the first plate 210 may comprise a channel 212. The channel 212 may be fully embedded within the first plate 210. The channel 212 may be a serpentine channel 212 that loops throughout the first plate 210. As can be appreciated, the serpentine structure of the channel 212 would be exceedingly difficult (if not impossible) to fabricate with subtractive machining processes. Accordingly, a 3D printing process is used to form the first plate 210 with such a channel 212. As shown, the channel 212 may include ends that do not exit a sidewall of the first plate 210. For example, the input/output to the channel 212 may be formed vertically into a bottom surface of the first plate 210, with the input/outputs fluidly coupled to the laterally oriented channel 212.

In an embodiment, the first plate 210 may also comprise a hole 208. The hole 208 may be positioned at an approximate center of the first plate 210, and the hole 208 may pass through an entire thickness of the first plate 210. The hole 208 may be used to accommodate a utilities conduit (not shown) used to provide electrical connections, gas connections, and/or the like to the remaining portion of the pedestal (e.g., the second plate (not shown)).

Referring now to FIG. 2B, a plan view illustration of the portion of the first plate 210 is shown, in accordance with an additional embodiment. In FIG. 2B the embedded channel 212 is omitted for simplicity. FIG. 2B illustrates and exemplary flow path for a gas that is to be flown in the gap G between the first plate 210 and the second plate (not shown). In the embodiment shown in FIG. 2B, gas inputs are provided in holes 209 proximate to a center of the first plate 210. The gas exits the holes 209 and flows 206 towards an edge 204 of the first plate 210. While the gas is shown as being introduced through holes 209, it is to be appreciated that some embodiments may alternatively introduce the gas through the central hole 208 and the holes 209 may be omitted.

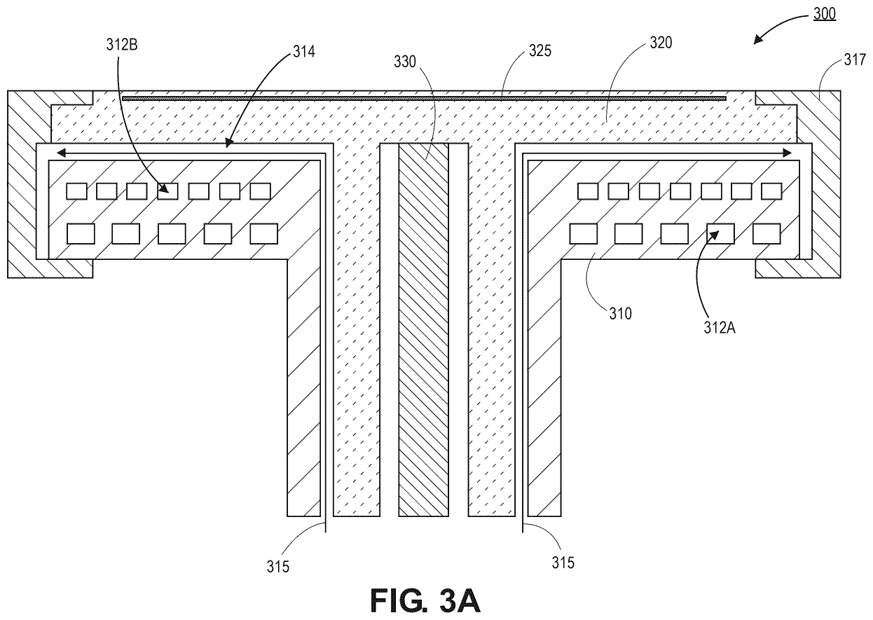

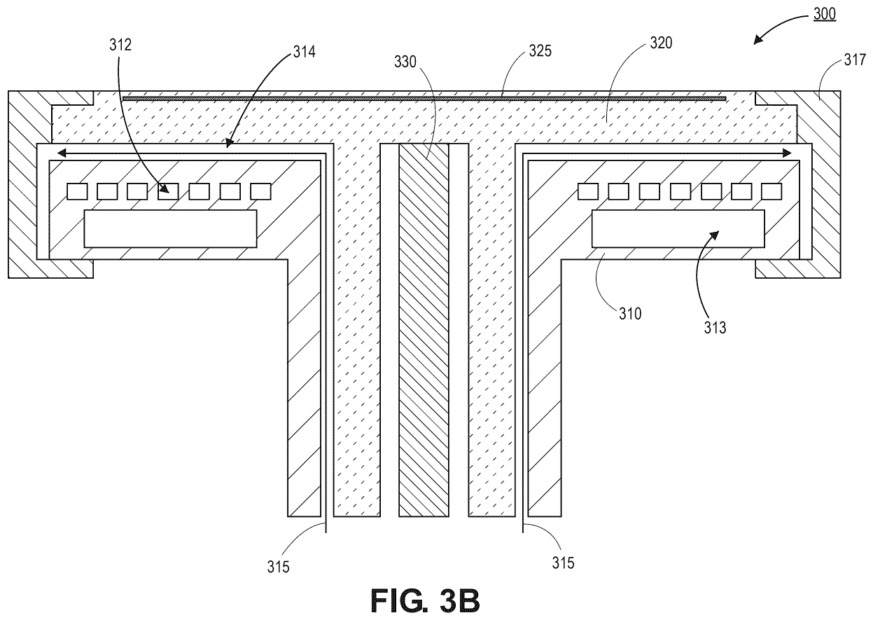

Referring now to FIG. 3A, a cross-sectional illustration of a portion of a pedestal 300 is shown, in accordance with an embodiment. In an embodiment, the pedestal 300 comprises a first plate 310 and a second plate 320. The first plate 310 may be similar to the first plate 110 described in greater detail herein, and the second plate 320 may be similar to the second plate 120 described in greater detail herein. In an embodiment, the first plate 310 may be separated from the second plate 320 by a gap 314. The gap 314 may be any suitable dimension suitable for flowing a gas 315 for implementing rapid heat transfer between the second plate 320 and the first plate 310. For example, the gap 314 may be up to up to approximately 750 μm, up to approximately 500 μm, up to approximately 250 μm, or up to approximately 100 μm. Though, larger gaps 314 may also be used in some embodiments.

In an embodiment, the second plate 320 may be an actively heated component. For example, a resistive heater 325 or the like may be provided in the second plate 320. In an embodiment, the first plate 310 may be actively cooled. For example, the first plate 310 may comprise fluidic channels 312 for flowing a cooled liquid. In an embodiment, a first layer of fluidic channels 312A and a second layer of fluidic channels 312B may be provided in the first plate 310. Though, any number of layers of fluidic channels 312 may be used in some embodiments.

The flow of fluid in the fluidic channels 312 conforms with vacuum chamber design rules because the first plate 310 is fabricated with a 3D printing process. That is, the first plate 310 is printed up, and there is no need to braze or otherwise mate and/or seal surfaces together in order to contain the fluid in the fluidic channels 312. In an embodiment, the first plate 310 comprises a material with a high thermal conductivity. For example, the first plate 310 may comprise aluminum or another suitable metallic material.

In an embodiment, an edge cap 317 is provided around the ends of the second plate 320 and the first plate 310. The edge cap 317 is sealed to the second plate 320 and the first plate 310 in order to prevent the gas 315 from flowing into the chamber. The gas 315 may flow through the gap 314 and between the edge cap 317 and the first plate 310. In some instances, a gas outlet (not shown) is provided to allow for a continuous flow of the gas 315. In other embodiments, there is no gas outlet, and the gas 315 is allowed to flow in when needed, and then the gas 315 is drawn back out through the input when not needed.

In an embodiment, the gas 315 allows for rapid heat transfer from the second plate 320 to the first plate 310. When no gas 315 is in the gap 314, the air provides a good thermal insulator. When the temperature of the second plate 320 needs to be rapidly lowered, the gas 315 is flown into the gap 314 to provide an improved thermal path (e.g., through an increase in convective thermal transfer) between the second plate 320 and the first plate 310.

In an embodiment, a utility conduit 330 may pass through a center of the pedestal 300. The utility conduit 330 may include electrical, gas, and/or fluid connections that are routed to various components of the pedestal 300. The utility conduit may include a vacuum channel to enable vacuum chucking. An electrical connection through the utility conduit may be coupled to a chucking electrode (not shown) when the pedestal 300 is used as an ESC.

Referring now to FIG. 3B, a cross-sectional illustration of a portion of a pedestal 300 is shown, in accordance with an additional embodiment. In an embodiment, the pedestal 300 in FIG. 3B is similar to the pedestal 300 in FIG. 3A, with the exception of the structure of the first plate 310. Instead of having multiple rows of fluidic channels 312 for cooling, the pedestal 300 in FIG. 3B has a single row of fluidic channels 312. Additionally, the first plate 310 may also comprise one or more cavities 313. The cavities 313 may reduce the mass of the first plate 310. In an embodiment, the cavities 313 may be completely sealed so that there is no inlet or outlet. In some instances, the cavities 313 may be hollow. For example, the cavities 313 may be filled with air or any other gas. Such a sealed cavity 313 is obtainable through the use of the 3D printing process.

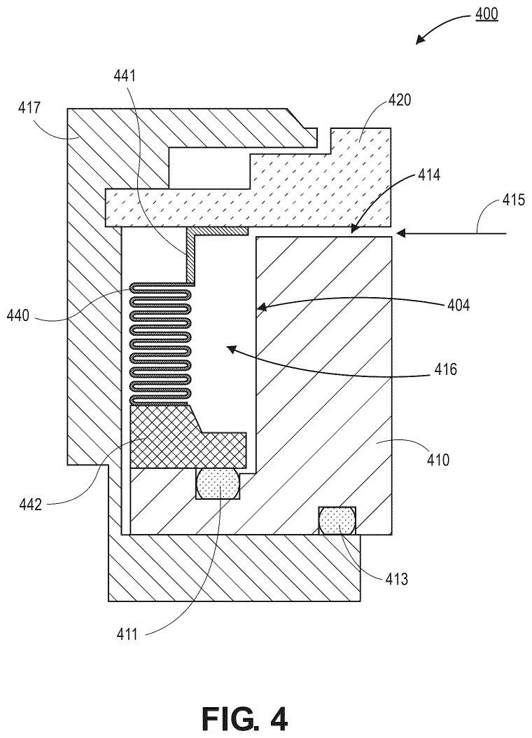

Referring now to FIG. 4, a cross-sectional illustration of a portion of a pedestal 400 is shown, in accordance with an embodiment. In FIG. 4, the edge region of the pedestal 400 is shown. As shown, the first plate 410 is spaced apart from the second plate 420 by a gap 414. The first plate 410 may be similar to any of the first plates described in greater detail herein, and the second plate 420 may be similar to any of the second plates described in greater detail herein. When heat transfer from the (heated) second plate 420 to the (cooled) first plate 410 is desired, a gas 415 may be flown into the gap 414.

As shown, the first plate 410 may be mechanically coupled to the second plate 420 along the edge region by an edge cap 417 and/or a seal ring 440. In order to thermally isolate the second plate 420 from the first plate 410, the seal ring 440 may function as a thermal choke. That is, the seal ring 440 may have a relatively low thermal conductivity. For example, the seal ring 440 may comprise a low thermal conductivity alloy that comprise nickel, cobalt, and iron. To further decrease heat transfer, the seal ring 440 may have a serpentine cross-section in order to increase a length of the thermal path. The serpentine cross-section may sometimes be referred to as having a bellows shape. In an embodiment, the seal ring 440 may be coupled to the second plate 420 by an insert 441, and the seal ring 440 may be coupled to the first plate 410 by a ring 442. The insert 441 and the ring 442 may also be low thermal conductivity materials. In an embodiment, the edge cap 417 may also be a low thermal conductivity material.

In an embodiment, the seal ring 440 may be adjacent to an edge 404 of the first plate 410. A gap 416 may be between the seal ring 440 and the edge 404 of the first plate 410 to provide an exit path for the gas 415 that flows along the gap 414 between the first plate 420 and the second plate 420. In an embodiment, the gap 416 may have a gas outlet (not shown) in order to remove gas 415 from the pedestal 400. Such an embodiment allows for the continuous flow of gas through the gap 414. In other embodiments, there may not be a gas outlet that is fluidly coupled to the gap 416.

In an embodiment, the ring 442 may press against an O-ring 411, a gasket, or the like. The O-ring 411 is pressed against the first plate 410 in order to provide a hermetic seal to prevent gas 415 from leaking from the gap 416 into the chamber around the pedestal 400. In some embodiments, a second O-ring 413 may be provided between the edge cap 417 and the first plate 410 as well.

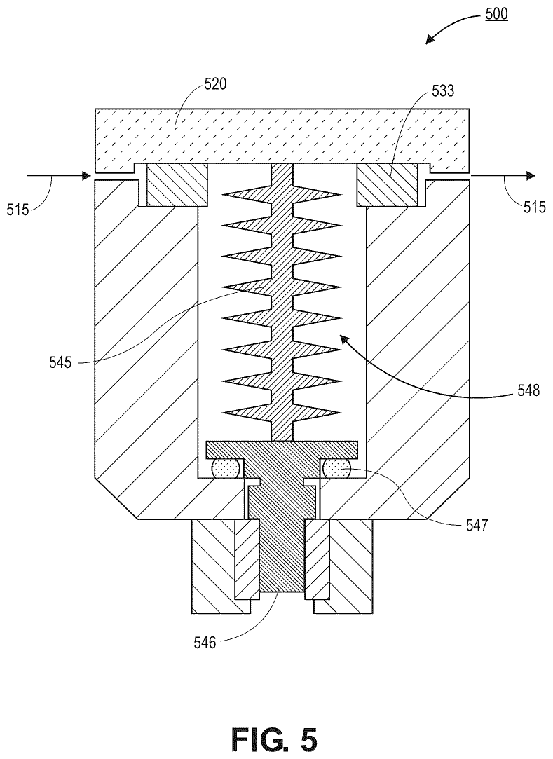

Referring now to FIG. 5, a cross-sectional illustration of a portion of a pedestal 500 is shown, in accordance with an embodiment. FIG. 5 illustrates a portion of the pedestal 500 around a lift pin. In an embodiment, the lift pin is within a housing 545 that is positioned within a hole 548 in the first plate 510. The second plate 520 is spaced away from the first plate 510 by a gap 514. In an embodiment, the first plate 510 and the second plate 520 may be similar to any of the first plates and second plates described in greater detail herein. In an embodiment, the hole 548 may pass through an entire thickness of the first plate 510.

A spacing ring 533 may be provided between the second plate 520 and the first plate 510 in some embodiments. In an embodiment, a mount 546 may be provided below the pin housing 545. In an embodiment, the mount 546 compresses an O-ring 547 or the like against the first plate 510 in order to provide a hermetic seal to the hole 548. The spacing ring 533 may also provide a hermetic seal around the hole 548. This allows gas 515 to flow through the gap 514 without entering the hole 548 and exiting out the bottom of the first plate 510 near the lift pin housing 545. In an embodiment, the lift pin within the housing 545 may be actuated in order to raise up through a hole (out of the plane of FIG. 5) in the second plate 520. The presence of the spacing ring 533 and the O-ring 547 provide a seal that prevents leakage of gasses into the vacuum within the chamber around the pedestal 500.

In an embodiment, similar hole and spacer structures may be provided through the first plate 510 in order to provide a pin that is used for securing the first plate 510 to the second plate 520. The pin may be hermetically sealed so that gas 515 does not leak out of the gap 514 or into the vacuum of the chamber environment.

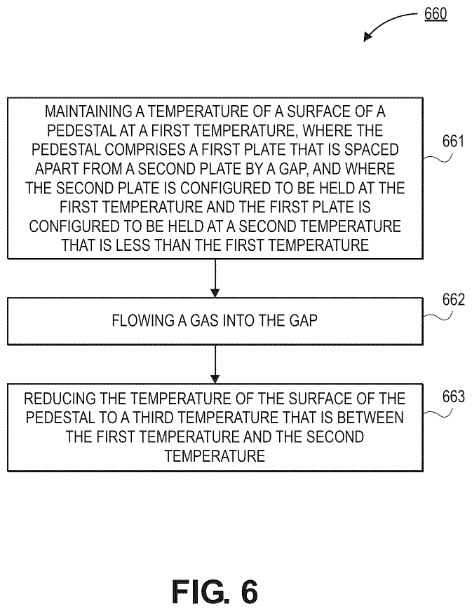

Referring now to FIG. 6, a process flow diagram of a process 660 for changing a temperature of a surface of a pedestal is shown, in accordance with an embodiment. In an embodiment, the process 660 may begin with operation 661, which comprises maintaining a temperature of a surface of a pedestal at a first temperature. In an embodiment, the pedestal comprises a first plate that is spaced apart from a second plate by a gap. For example, the first plate and the second plate of the pedestal may be similar to any of the first plates and the second plates described in greater detail herein. In an embodiment, the surface of the pedestal may be a surface of the second plate.

In an embodiment, the second plate is configured to be held at the first temperature, and the first plate is configured to be held at a second temperature that is lower than the first temperature. The first plate may be liquid cooled by flowing a cooling fluid through seamless channels that are fully embedded within the first plate. The first plate may be formed with a 3D printing process. In an embodiment, the second plate may be held at the first temperature by an embedded heating element, such as a resistive heating element. In an embodiment, the first plate may be substantially thermally isolated from the second plate. For example, the first plate may not directly contact the second plate. Further, any significant form of heat transfer from the first plate to the second plate may occur through radiation and/or conduction. That is, a fluid (e.g., gas) may not be flowing through the gap during operation 661.

In an embodiment, the process 660 may continue with operation 662, which comprises flowing a gas into the gap. In an embodiment, the gas may include one or more of hydrogen, nitrogen, helium, or any other inert gas. The flow of gas into the gap may include a continuous flow of the gas from an inlet to and outlet. In other embodiments, the flow of gas may include flowing the gas into the gap through an inlet without the presence of an outlet. In such an embodiment, the gap may be considered as being pressurized with the gas.

In an embodiment, the process 660 may continue with operation 663, which comprises reducing the temperature of the surface of the pedestal to a third temperature that is between the first temperature and the second temperature. In an embodiment, the reduction in temperature of the surface of the pedestal may be provided through an increase in convective cooling of the second plate. For example, as a flow rate of the gas in the gap increases, the convective cooling effect is increased. In an embodiment, the difference between the first temperature and the third temperature may be approximately 50° C. or more, or approximately 100° C. or more. Though, smaller temperature drops are also enabled. Further, the temperature change of the surface of the pedestal may be completed in about one minute or less, about forty five seconds or less, or about thirty seconds or less. In an embodiment, the rate of cooling for the surface of the pedestal may be increased further by switching off (or reducing the power) to the heating element in the second plate.

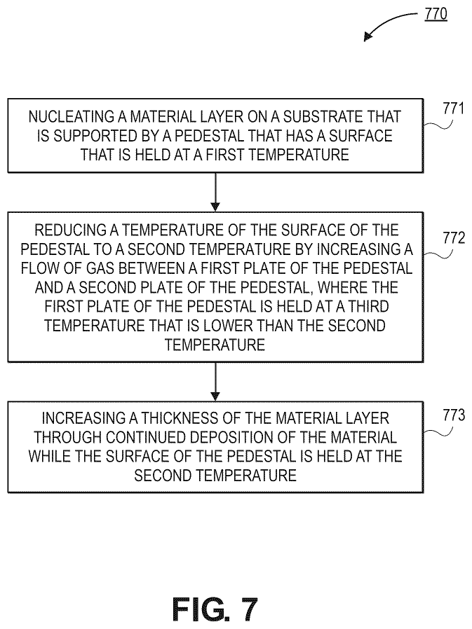

Referring now to FIG. 7, a process flow diagram of a process 770 for depositing a layer on a substrate with a process recipe that comprises two different substrate temperatures is shown, in accordance with an embodiment. In an embodiment, the process 770 may begin with operation 771, which comprises nucleating a material layer on a substrate that is supported by a pedestal that has a surface that is held at a first temperature. In an embodiment, the material layer may comprise a metallic material, such as tungsten. The substrate may be a semiconductor substrate, such as a silicon wafer or the like. In an embodiment, the deposition process used for the nucleation may include CVD, PECVD, PEALD, PVD, or the like. In an embodiment, the first temperature may be approximately 400° C. or higher or approximately 450° C. or higher. Though, the first temperature may also be below 400° C. in other embodiments.

In an embodiment, the process 770 may continue with operation 772, which comprises reducing a temperature of the surface of the substrate to a second temperature by increasing a flow of gas between a first plate of the pedestal and a second plate of the pedestal. In an embodiment, the first plate of the pedestal is held at a third temperature that is lower than the second temperature. The surface of the substrate that is reduced to the second temperature may be a surface of the second plate. In an embodiment, the first plate and the second plate may be similar to any of the first plates or second plates described in greater detail herein. In an embodiment, flowing the gas between the first plate and the second plate increases the convective heat transfer from the second plate to the first plate in order to rapidly drop the temperature of the surface. For example, the difference between the first temperature and the second temperature may be 50° C. or more, or 100° C. or more. Further, the change from the first temperature to the second temperature may be completed in about one minute or less, about forty five seconds or less, or about thirty seconds or less. In an embodiment, the first plate may be held at a third temperature that is approximately 100° C. or below, approximately 50° C. or below, or approximately 0° C. or below.

In an embodiment, the process 770 may continue with operation 773, which comprises increasing a thickness of the material layer through continued deposition of the material while the surface of the pedestal is held at the second temperature. In an embodiment, the lower second temperature may be maintained through control of the gas flow rate between the first plate and the second plate. Control of a heating element within the second plate may also be used in order to maintain the second temperature.

While process 770 includes a deposition process for starting at a relatively high temperature and rapidly decreasing the temperature, it is to be appreciated that a low temperature may be rapidly increased to a higher temperature. For example, at the initial low temperature condition, a high gas flow rate between the first plate and the second plate may be provided. Then, the gas flow rate may be reduced or brought to zero in order to substantially thermally isolate the second plate. This allows for rapid heating of the second plate from a heating element embedded in the second plate.

Embodiments disclosed herein may include a method that comprises nucleating a material layer on a substrate that is supported by a pedestal that has a surface that is held at a first temperature, and reducing a temperature of the surface of the pedestal to a second temperature by increasing a flow of gas between a first plate of the pedestal and a second plate of the pedestal. In an embodiment, the first plate of the pedestal is held at a third temperature that is lower than the second temperature, and the surface of the pedestal is part of the second plate of the pedestal. In an embodiment, the method further comprises increasing a thickness of the material layer through continued deposition of the material while the surface of the pedestal is held at the second temperature.

Embodiments may also comprise a method of the previous paragraph, where the first plate of the pedestal is cooled with a fluid that passes through a channel embedded within the first plate of the pedestal.

Embodiments may also comprise a method of either of the previous two paragraphs, where the first plate of the pedestal is formed with a three-dimensional printing process.

Embodiments may also comprise a method of either of the previous three paragraph, where the material layer comprises tungsten.

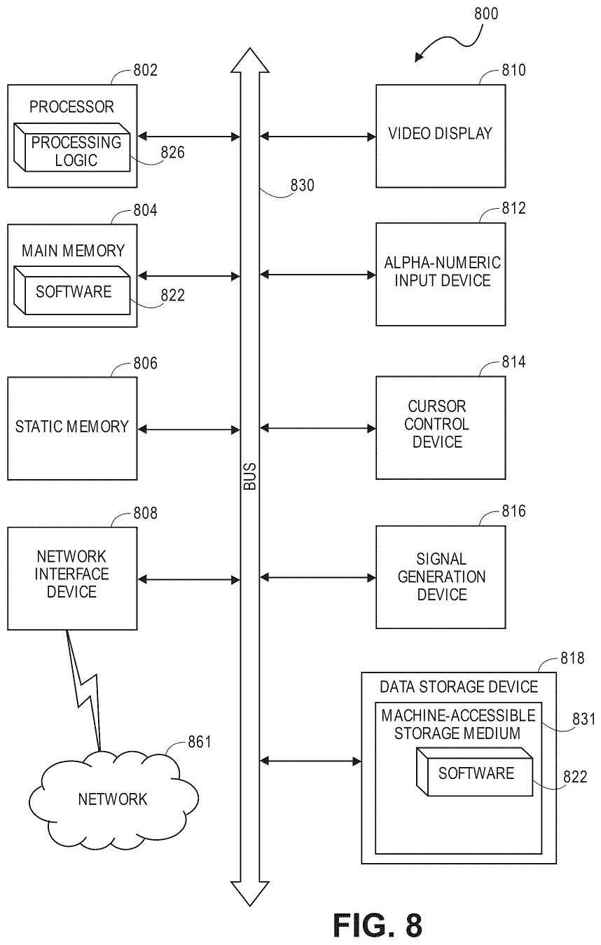

Referring now to FIG. 8, a block diagram of an exemplary computer system 800 of a processing tool is illustrated in accordance with an embodiment. In an embodiment, computer system 800 is coupled to and controls processing in the processing tool. The computer system 800 may be communicatively coupled to a pedestal with a cooled first plate and a heated second plate with a gap between the first plate and the second plate.

Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include processes for rapidly changing a temperature of a pedestal by controlling a flow of a gas between a cooled first plate and a heated second plate.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a first plate with an embedded channel that has a seamless surface, and wherein the first plate comprises a metallic material;
a second plate over the first plate, wherein the second plate is spaced apart from the first plate by a gap; and
a heating element embedded within the second plate.

2. The apparatus of claim 1, wherein the gap is up to 750 μm.

3. The apparatus of claim 1, further comprising:
a spacer between the first plate and the second plate.

4. The apparatus of claim 1, further comprising:
a gas input fluidically coupled to the gap; and
a gas output fluidically coupled to the gap.

5. The apparatus of claim 1, further comprising:
a cavity in the first plate, wherein the cavity is completely sealed.

6. The apparatus of claim 1, further comprising:
a seal ring between the first plate and the second plate, wherein the seal ring has a serpentine cross-section.

7. The apparatus of claim 6, wherein the seal ring is adjacent to a sidewall of the first plate and below a surface of the second plate that faces the first plate.

8. The apparatus of claim 1, further comprising:
a hole through a thickness of the first plate; and
an O-ring around the hole between the first plate and the second plate.

9. The apparatus of claim 8, further comprising:
a pin within the hole.

10. The apparatus of claim 1, wherein the first plate comprises aluminum.

11. A pedestal, comprising:
a first plate, wherein the first plate is configured to be held at a first temperature by a cooled liquid that passes through a channel embedded within the first plate, and wherein the first plate is a monolithic metallic structure;
a second plate above the first plate, wherein the second plate is configured to be held at a second temperature that is higher than the first temperature by a heating element embedded in the second plate; and
a gap between the first plate and the second plate, wherein initiating a flow of a gas through the gap reduces a temperature of the second plate to a third temperature that is between the first temperature and the second temperature.

12. The pedestal of claim 11, wherein the pedestal is within a chamber configured to support a vacuum.

13. The pedestal of claim 11, wherein the first plate is a three-dimensionally printed monolithic metallic structure.

14. The pedestal of claim 11, further comprising:
a seal between the first plate and the second plate, wherein the seal is a material with a thermal conductivity that is lower than a thermal conductivity of the first plate.

15. The pedestal of claim 14, wherein the seal comprises nickel, cobalt, and iron.

16. The pedestal of claim 11, wherein an input to the fluidic path is proximate to a center of the first plate, and wherein an output to the fluidic path is at an edge of the first plate.

17. A method, comprising:
maintaining a temperature of a surface of a pedestal at a first temperature, wherein the pedestal comprises a first plate that is spaced apart from a second plate by a gap, and wherein the second plate is configured to be held at the first temperature and the first plate is configured to be held at a second temperature that is less than the first temperature;
flowing a gas into the gap; and
reducing the temperature of the surface of the pedestal to a third temperature that is between the first temperature and the second temperature.

18. The method of claim 17, wherein the temperature of the surface of the pedestal is reduced from the first temperature to the third temperature in less than one minute.

19. The method of claim 17, wherein the third temperature is at least 100° C. less than the first temperature.

20. The method of claim 17, wherein the first plate of the pedestal is formed with a three-dimensional printing process.
